(19) United States
(12) Patent Application Publication
(10) Pub. No.: US 2025/0372350 A1
(43) Pub. Date: Dec. 4, 2025

(54) Substrate Processing Method and Substrate Processing Apparatus

(71) Applicant: Tokyo Electron Limited, Tokyo (JP)

(72) Inventors: Syuji NOZAWA, Yamanashi (JP); Tatsuya YAMAGUCHI, Yamanashi (JP)

(21) Appl. No.: 19/213,239

(22) Filed: May 20, 2025

(30) Foreign Application Priority Data
May 28, 2024 (JP) 2024-086051

(51) Int. Cl. H01J 37/32; C23C 16/44; C23C 16/52

(52) U.S. Cl. CPC H01J 37/32449; H01J 37/32834; C23C 16/4408; C23C 16/52; H01J 2237/332

(57) ABSTRACT

There is a substrate processing method performed in a substrate processing apparatus, the apparatus including: a processing chamber; a first supply line configured to supply a first source gas into the chamber; a second supply line configured to supply the first source gas into the chamber; an exhaust line configured to exhaust a gas; a first vent line that connects the first supply line and the exhaust line; and a second vent line that connects the second supply line and the exhaust line, wherein the method comprises: (a) supplying the first source gas into the processing chamber from one of the first supply line and the second supply line; and (b) cleaning the other of the first supply line and the second supply line through the first vent line or the second vent line connected to the other of the first supply line and the second supply line.

### CROSS-REFERENCE TO RELATED APPLICATIONS

This application claims priority to Japanese Patent Application No. 2024-086051 filed on May 28, 2024, the entire contents of which are incorporated herein by reference.

### TECHNICAL FIELD

The present disclosure relates to a substrate processing method and a substrate processing apparatus.

### BACKGROUND

For example, Japanese Laid-open Patent Publication No. 2010-87238 discloses a film forming apparatus that performs a cycle of alternately supplying and exhausting a first reactive gas and a second reactive gas into a vacuum chamber multiple times to allow the reactive gases to react each other and form a thin film on a surface of a substrate. The film forming apparatus includes a purge gas supply part for supplying a purge gas to a processing space between the timing of supplying the first reactive gas and the timing of supplying the second reactive gas.

For example, Japanese Laid-open Patent Publication No. 2004-6733 discloses a substrate processing apparatus that includes a substrate holder for holding a substrate to be processed, a processing chamber that is exhausted at an exhaust port, and a raw material gas supply system that alternately supplies a first and a second raw material gas into the processing chamber in the form of laminar flow.

### SUMMARY

The present disclosure provides a substrate processing method and a substrate processing apparatus capable of reducing particles without deteriorating throughput.

In accordance with an exemplary embodiment of the present disclosure, there is a substrate processing method performed in a substrate processing apparatus, wherein the substrate processing apparatus includes: a processing chamber; a first supply line configured to supply a first source gas into the processing chamber; a second supply line configured to supply the first source gas into the processing chamber; an exhaust line configured to exhaust a gas; a first vent line that connects the first supply line and the exhaust line; and a second vent line that connects the second supply line and the exhaust line, the substrate processing method comprising: (a) supplying the first source gas into the processing chamber from one of the first supply line and the second supply line; and (b) cleaning the other of the first supply line and the second supply line through the first vent line or the second vent line connected to the other of the first supply line and the second supply line.

### BRIEF DESCRIPTION OF THE DRAWINGS

FIG. 1 is a schematic diagram of a substrate processing apparatus according to a reference example.

FIG. 2 is a schematic diagram of a substrate processing apparatus according to an embodiment.

FIG. 3 is a flowchart showing a substrate processing method according to an embodiment.

FIG. 4 is a diagram showing an example of a recipe for simultaneously performing film formation and cleaning.

FIG. 5 is a schematic diagram of a substrate processing apparatus according to an embodiment.

### DETAILED DESCRIPTION

Hereinafter, embodiments of a substrate processing method and a substrate processing apparatus of the present disclosure will be described in detail with reference to the accompanying drawings. Further, the embodiments are not intended to limit the substrate processing method and the substrate processing apparatus of the present disclosure. The following embodiments can be appropriately combined without contradicting configurations and processing contents of the present disclosure.

Further, the drawings to be referred to below to are schematic for convenience of description. Therefore, the details thereof may be omitted, and the dimensional ratios in the drawings do not necessarily indicate the actual ratios.

### (Substrate Processing Apparatus According to Reference Example)

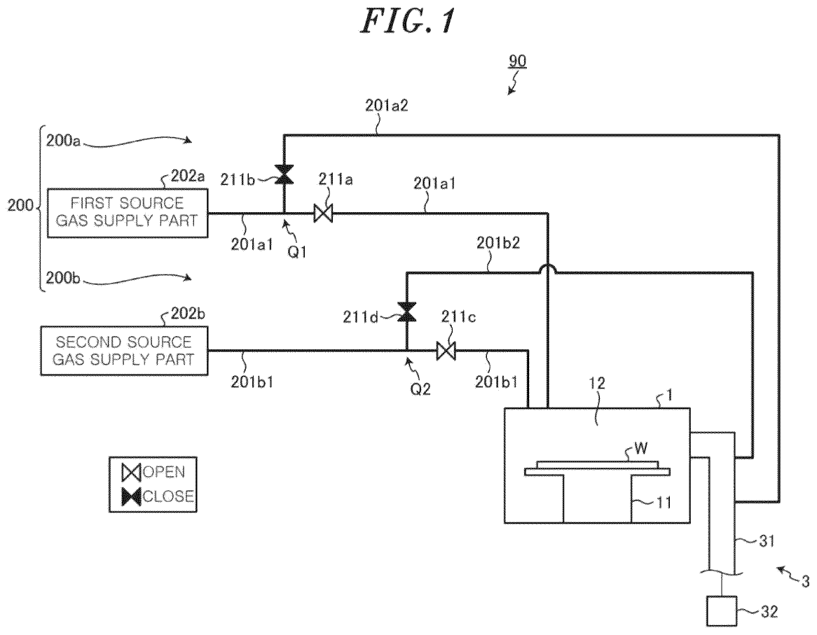

A substrate processing apparatus according to a reference example will be briefly described with reference to FIG. 1 and, then, a substrate processing apparatus according to an embodiment of the present disclosure will be described. FIG. 1 is a schematic diagram of the substrate processing apparatus according to the reference example.

A substrate processing apparatus 90 according to the reference example includes a processing chamber 1, an exhaust system 3, and a gas supply part 200. Further, the substrate processing apparatus 90 includes a substrate support 11. The substrate support 11 is located in the processing chamber 1, and supports a substrate. The processing chamber 1 has a processing space 12 defined by a ceiling wall and a sidewall of the processing chamber 1 and the substrate support 11. The processing chamber 1 is made of a conductor such as aluminum or the like, and is grounded. The exhaust system 3 includes an exhaust line 31 and an exhaust device 32. The exhaust line 31 is connected to a gas exhaust port provided at the processing chamber 1. The exhaust device 32 exhausts a gas.

The gas supply part 200 includes two systems of gas auxiliary supply parts, i.e., a gas supply part 200a and a gas supply part 200b. The gas supply part 200a has a first source gas part 202a and a supply line 201a1. The gas supply part 200b has a second source gas part 202b and a supply line 201b1. A vent line 201a2 branches from the supply line 201a1 at a branch point Q1, and connects the supply line 201a1 to the exhaust line 31. A vent line 201b2 branches from the supply line 201b1 at a branch point Q2, and connects the supply line 201b1 to the exhaust line 31.

The supply line 201a1 is provided with a first on-off valve 211a at the downstream side of the branch point Q1. The vent line 201a2 is provided with a second on-off valve 211b. The first on-off valve 211a controls start and stop of the supply of the first source gas/the supply and shutoff of the first source gas, from the supply line 201a1 to the processing chamber 1. The second on-off valve 211b controls start and stop of the exhaust of the first source gas from the vent line 201a2 to the exhaust line 31.

The supply line 201b1 is provided with a third on-off valve 211c at the downstream side of the branch point Q2. The vent line 201b2 is provided with a fourth on-off valve 211d. The third on-off valve 211c controls start and stop of the supply of the second source gas from the supply line 201b1 to the processing chamber 1. The fourth on-off valve 211d controls start and stop of the exhaust of the second source gas from the vent line 201b2 to the exhaust line 31.

The on-off valves shown in white indicate an open state, and the on-off valves shown in black indicate a closed state. In the example of FIG. 1, the first on-off valve 211a and the third on-off valve 211c are opened, and the second on-off valve 211b and the fourth on-off valve 211d are closed. As a result, the first source gas and the second source gas are supplied from the supply line 201a1 and the supply line 201b1 to the processing chamber 1. The first source gas and the second source gas react in the processing space 12, and a film such as an organic film or the like is formed on the substrate W.

In a film forming process for an organic film, such as polyurea, polyimide, polyamide, polyurethane, or the like, using a deposition polymerization method, the first source gas and the second source gas are supplied at a high concentration, or these source gases are supplied for a long period of time. As a result, particles may be generated in the piping of the supply line 201a1 and the supply line 201b1.

In order to deal with particles, the supply line 201a1 and the supply line 201b1 have been conventionally evacuated and purged with a purge gas. In this case, a process of evacuating and purging the supply line after the film formation is added to suppress the generation of particles, but the throughput deteriorates.

On the other hand, in a substrate processing apparatus according to an embodiment of the present disclosure, two gas systems, each including a gas supply line and a vent line, are arranged. Further, in the substrate processing apparatus, a source gas is supplied into the processing chamber 1 using one supply line of the two gas systems and, at the same time, the other supply line is exhausted and purged through the vent line. Therefore, the substrate processing apparatus can perform the film formation on the substrate and the cleaning of the supply line at the same time. Accordingly, in the substrate processing apparatus, it is not necessary to add a process of exhausting and purging the supply line after the film formation. As a result, the substrate processing apparatus can reduce particles without reducing throughput. Hereinafter, a substrate processing apparatus and a substrate processing method according to an embodiment will be described.

### (Substrate Processing Apparatus)

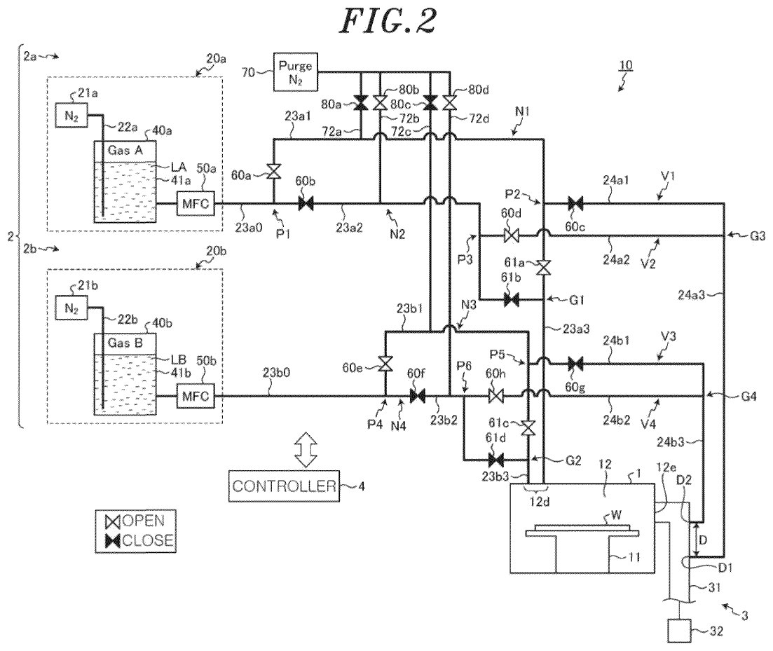

The configuration of a substrate processing apparatus according to an embodiment of the present disclosure will be described with reference to FIG. 2.

FIG. 2 is a schematic diagram of a substrate processing apparatus according to an embodiment.

The substrate processing apparatus 10 performs processing such as film formation or the like on the substrate W. For example, the substrate processing apparatus 10 performs a film forming process using a vapor deposition polymerization method for forming an organic film such as polyurea, polyimide, polyamide, polyurethane. The substrate W may be a semiconductor wafer or a glass substrate. The film formation may be performed using a chemical vapor deposition (CVD) method, an atomic layer deposition (ALD) method, or other film forming methods. The substrate processing apparatus 10 may be a single-wafer type substrate processing apparatus or a batch type substrate processing apparatus.

The substrate processing apparatus 10 includes a processing chamber 1, a gas supply part 2, an exhaust system 3, and a controller 4. Further, the substrate processing apparatus 10 includes a substrate support 11. The substrate support 11 supports the substrate W. The substrate support 11 is located in the processing chamber 1. The processing chamber 1 has a processing space 12 defined by the ceiling wall and the sidewall of the processing chamber 1 and the substrate support 11. The processing chamber 1 is made of a conductor such as aluminum or the like, and is grounded.

The processing chamber 1 has at least one gas supply port 12d for supplying a gas to the processing space 12 and at least one gas exhaust port 12e for exhausting a gas from the plasma processing space. The gas supply port 12d is connected to the gas supply part 2. The gas exhaust port is connected to the exhaust system 3. An opening (not shown) is formed in the sidewall of the processing chamber 1 for loading a substrate W into the processing chamber 1 and unloading the substrate W from the processing chamber 1. The opening is opened and closed by a gate valve (not shown).

The exhaust system 3 includes an exhaust line 31 and an exhaust device 32. The exhaust line 31 is connected to the exhaust device 32, and is configured to exhaust a gas by the exhaust device 32. The exhaust device 32 may include a pressure control valve and a vacuum pump. The pressure control valve adjusts a pressure in the processing space 12s. The vacuum pump may include a turbo molecular pump, a dry pump, or a combination thereof.

The gas supply part 2 has a first gas supply part 2a and a second gas supply part 2b. The first gas supply part 2a has two systems of supply lines. The two supply lines of the first gas supply part 2a include a first supply path N1 consisting of a supply line 23a0, a supply line 23a1, and a supply line 23a3, and a second supply path N2 consisting of a supply line 23a0, a supply line 23a2, and a supply line 23a3.

The supply line 23a0 is connected to the source gas supply part 20a. The supply line 23a0 branches into a supply line 23a1 and a supply line 23a2 at a branch point P1. The supply line 23a1 and the supply line 23a2 are joined to the supply line 23a3 at a joining point G1.

The source gas supplied by the source gas supply part 20a may be a first source gas. In this case, the first supply path N1 is an example of a first supply line configured to supply the first source gas into the processing chamber 1. The second supply path N2 is an example of a second supply line configured to supply the first source gas into the processing chamber 1. However, the source gas supplied by the source gas supply part 20a may be a second source gas. In this case, the first supply path N1 is an example of a third supply line configured to supply the second source gas into the processing chamber 1. The second supply path N2 is an example of a fourth supply line configured to supply the second source gas into the processing chamber 1.

The vent lines connected to the source gas supply part 20a include a first vent path V1 consisting of a vent line 24a1 and a vent line 24a3, and a second vent path V2 consisting of a vent line 24a2 and a vent line 24a3. The first vent path V1 is connected to the first supply path N1. The second vent path V2 is connected to the second supply path N2. The vent line 24a1 branches off from the supply line 23a1 at a branch point P2. The vent line 24a2 branches off from the supply line 23a2 at a branch point P3. The vent line 24a1 and the vent line 24a2 are joined to the vent line 24a3 at a joining point G3. The vent line 24a3 is connected to the exhaust line 31.

The first vent path V1 is an example of a first vent line that connects the first supply line and the exhaust line 31. The second vent path V2 is an example of a second vent line that connects the second supply line and the exhaust line 31.

The two systems of supply lines of the second gas supply part 2b include a third supply path N3 consisting of supply lines 23b0, 23b1, and 23b3, and a fourth supply path N4 consisting of supply lines 23b0, 23b2, and 23b3.

The supply line 23b0 is connected to the source gas supply part 20b. The supply line 23b0 branches into supply lines 23b1 and 23b2 at a branch point P4. The supply line 23b1 and the supply line 23b2 are joined to the supply line 23b3 at the joining point G2.

The source gas supplied by the source gas supply part 20b may be, for example, a second source gas, different from the source gas supplied by the source gas supply part 20a. In this case, the third supply path N3 is an example of a third supply line configured to supply the second source gas into the processing chamber 1. The fourth supply path N4 is an example of a fourth supply line configured to supply the second source gas into the processing chamber 1. However, when the source gas supplied by the source gas supply part 20a is the second source gas, the source gas supplied by the source gas supply part 20b may be the first source gas. In this case, the third supply path N3 is an example of a first supply line configured to supply the first source gas into the processing chamber 1. The fourth supply path N4 is an example of a second supply line configured to supply the first source gas into the processing chamber 1.

The vent line connected to the source gas supply part 20b side includes a third vent path V3 consisting of a vent line 24b1 and a vent line 24b3, and a fourth vent path V4 consisting of a vent line 24b2 and a vent line 24b3. The third vent path V3 is connected to the third supply path N3. The fourth vent path V4 is connected to the fourth supply path N4. The vent line 24b1 branches off from the supply line 23b1 at a branch point P5. The vent line 24b2 branches off from the supply line 23b2 at a branch point P6. The vent line 24b1 and the vent line 24b2 are joined to the vent line 24b3 at a joining point G4. The vent line 24b3 is connected to the exhaust line 31.

The third vent path V3 is an example of a third vent line that connects the third supply line and the exhaust line 31. The fourth vent path V4 is an example of a fourth vent line that connects the fourth supply line and the exhaust line 31.

The source gas supply part 20a includes a carrier gas supply part 21a, a first vaporizer 40a, and a first flow rate controller 50a. The carrier gas supply part 21a is connected to the carrier gas supply line 22a. The carrier gas supply part 21a supplies N2 gas to the first vaporizer 40a. N2 gas is an example of a carrier gas. The carrier gas is not limited thereto, and may be an inert gas such as He gas or the like. The first vaporizer 40a is connected to the supply line 23a0 via the first flow rate controller 50a.

The first vaporizer 40a has a tank 41a that contains a liquid first source LA. N2 gas flows through the carrier gas supply line 22a, and is supplied to the tank 41a. The first vaporizer 40a vaporizes the first source LA by heating, and outputs a mixture of the vaporized first source gas and N2 gas as a source gas. The first source LA is not limited to liquid, and may be a solid.

The source gas supply part 20a supplies the source gas from the first supply path N1 or the second supply path N2 into the processing chamber 1. Hereinafter, GasA illustrated in FIG. 1 will be described as the first source gas.

The source gas supply part 20b includes a carrier gas supply part 21b, a second vaporizer 40b, and a second flow rate controller 50b. The carrier gas supply part 21b is connected to the carrier gas supply line 22b. The carrier gas supply part 21b supplies N2 gas to the second vaporizer 40b. N2 gas is an example of a carrier gas. The carrier gas is not limited thereto, and may be an inert gas such as He gas or the like.

The second vaporizer 40b has a tank 41b that contains a liquid second source material LB. N2 gas flows through the carrier gas supply line 22b, and is supplied to the tank 41b. The second vaporizer 40b vaporizes the second source material LB by heating, and outputs a mixture of the vaporized second source gas and N2 gas as a source gas. Further, the second source material LB is not limited to liquid, and may be a solid.

The source gas supply part 20b supplies a source gas into the processing chamber 1 from the third supply path N3 or the fourth supply path N4. Hereinafter, GasB illustrated in FIG. 1 will be described as the second source gas.

The first flow rate controller 50a and the second flow rate controller 50b are mass flow controllers (MFC). They have flow rate control valves, and control the flow rates of the first source gas and the second source gas.

The first supply path N1 has a first on-off valve 60a provided in the supply line 23a1 at the downstream side of the branch point P1. The second supply path N2 has a second on-off valve 60b provided in the supply line 23a2 at the downstream side of the branch point P1. The start and stop of the supply of the first source gas GasA are controlled by opening and closing the first on-off valve 60a and the second on-off valve 60b. Specifically, one of the first on-off valve 60a and the second on-off valve 60b is controlled to be in an open state, and the other on-off valve is controlled to be in a closed state. As a result, the first source gas is supplied from one of the supply lines 23a1 and 23a2, and the supply of the first source gas to the other of the supply lines 23a1 and 23a2 is stopped.

The first vent path V1 has a third on-off valve 60c provided in the vent line 24a1 at the downstream side of the branch point P2. The second vent path V2 has a fourth on-off valve 60d provided in the vent line 24a2 at the downstream side of the branch point P3. The start and stop of the exhaust of the first source gas are controlled by opening and closing the third on-off valve 60c and the fourth on-off valve 60d. Specifically, one of the third on-off valve 60c and the fourth on-off valve 60d is controlled to be in an open state, and the other on-off valve is controlled to be in a closed state. As a result, the first source gas is exhausted through one of the vent lines 24a1 and 24a2 from one of the supply lines 23a1 and 23a2, and the exhaust of the first source gas from the other vent line is stopped.

The third supply path N3 has a fifth on-off valve 60e provided in the supply line 23b1 at the downstream side of the branch point P4. The fourth supply path N4 has a sixth on-off valve 60f provided in the supply line 23b2 at the downstream side of the branch point P4. The start and stop of the supply of the second source gas GasB are controlled by opening and closing the fifth on-off valve 60e and the sixth on-off valve 60f. Specifically, one of the fifth on-off valve 60e and the sixth on-off valve 60f is controlled to be in an open state, and the other on-off valve is controlled to be in a closed state. As a result, the second source gas is supplied from one of the supply lines 23b1 and 23b2, and the supply of the second source gas to the other gas supply line is stopped.

The third vent path V3 has a seventh on-off valve 60g provided in the vent line 24b1 at the downstream side of the branch point P5. The fourth vent path V4 has an eighth on-off valve 60h provided in the vent line 24b2 at the downstream side of the branch point P6. The seventh on-off valve 60g and the eighth on-off valve 60h are opened and closed to control the start and stop of the exhaust of the second source gas. Specifically, one of the seventh on-off valve 60g and the eighth on-off valve 60h is controlled to be in an open state and the other on-off valve is controlled to be in a closed state. As a result, the second source gas is exhausted through one of the vent line 24b1 and the vent line 24b2 from one of the supply line 23b1 and the supply line 23b2, and the exhaust of the second source gas from the other vent line is stopped.

Further, the first supply path N1 has a ninth on-off valve 61a provided in the supply line 23a1 at the upstream side of the junction G1. The second supply path N2 has a tenth on-off valve 61b provided in the supply line 23a2 at the upstream side of the junction G1. Between the ninth on-off valve 61a and the tenth on-off valve 61b, the on-off valve located on the supply line to which the first source gas is supplied is opened, and the on-off valve located on the supply line to which the first source gas is not supplied is closed. As a result, when the first source gas flows through one of the supply line 23a1 and the supply line 23a2, the ninth on-off valve 61a and the tenth on-off valve 61b can prevent the first source gas from flowing back to the other supply line. The ninth on-off valve 61a and the tenth on-off valve 61b may be omitted.

Further, the third supply path N3 has an eleventh on-off valve 61c provided in the supply line 23b1 at the upstream side of the joining point G2. The fourth supply path N4 has a twelfth on-off valve 61d provided in the supply line 23b2 at the upstream side of the joining point G2. Between the eleventh on-off valve 61c and the twelfth on-off valve 61d, the on-off valve located on the supply line to which the second source gas is supplied is opened, and the on-off valve located on the supply line to which the second source gas is not supplied is closed. Accordingly, when the second source gas flows through one of the supply line 23b1 and the supply line 23b2, the eleventh on-off valve 61c and the twelfth on-off valve 61d can prevent the second source gas from flowing back to the other supply line. The eleventh on-off valve 61c and the twelfth on-off valve 61d may be omitted.

A distance D between a connection position D1 of the vent line 24a3 and the exhaust line 31 and a connection position D2 of the vent line 24b3 and the exhaust line 31 is several tens of centimeters or more. Therefore, the first source gas exhausted from the vent line 24a3 to the exhaust line 31 and the second source gas exhausted from the vent line 24b3 to the exhaust line 31 are not mixed in the exhaust line 31. Hence, in the substrate processing apparatus 10, the film formation inside the exhaust line 31 can be avoided.

The purge gas supply part 70 supplies N2 gas as an example of a purge gas. However, the purge gas is not limited to N2 gas, and may be an inert gas such as Ar gas. The purge gas supply part 70 is connected to the first supply path N1 to the fourth supply path N4 through the first purge gas path 72a to the fourth purge gas path 72d. The first purge gas path 72a connects the supply line 23a1 and the purge gas supply part 70. The first purge gas path 72a is provided with a thirteenth on-off valve 80a. The second purge gas path 72b connects the supply line 23a2 and the purge gas supply part 70. The second purge gas path 72b is provided with a fourteenth on-off valve 80b. The third purge gas path 72c connects the supply line 23b1 and the purge gas supply part 70. The third purge gas path 72c is provided with a fifteenth on-off valve 80c. The fourth purge gas path 72d connects the supply line 23b2 and the purge gas supply part 70. The fourth purge gas path 72d is provided with a sixteenth on-off valve 80d.

One of the thirteenth on-off valve 80a and the fourteenth on-off valve 80b is controlled to be in an open state, and the other on-off valve is controlled to be in a closed state. As a result, N2 gas is supplied to one of the supply lines 23a1 and 23a2, and the supply of N2 gas to the other supply line is stopped. In addition, one of the fifteenth on-off valve 80c and the sixteenth on-off valve 80d is controlled to be in an open state, and the other on-off valve is controlled to be in a closed state. As a result, N2 gas is supplied to one of the supply lines 23b1 and 23b2, and the supply of N2 gas to the other supply line is stopped.

The controller 4 processes computer-executable instructions that cause the substrate processing apparatus 10 to perform various processes included in the substrate processing method described in the present disclosure. The controller 4 may be configured to control individual components of the substrate processing apparatus 10 to perform various processes described herein. In one embodiment, the controller 4 may be partially or entirely included in the substrate processing apparatus 10. The controller 4 may include a processing part, a storage part, and a communication interface. The controller 4 is realized by, for example, a computer. The processing part reads a program from the storage part, and executes the read program. Accordingly, various control operations can be performed. The program may be stored in the storage part in advance, or may be acquired via a medium when necessary. The acquired program is stored in the storage prat, and is read from the storage part and executed by the processing part. The medium may be various computer-readable storage media, or may be a communication line connected to the communication interface. The processing part may be a central processing unit (CPU). The storage part may include a random access memory (RAM), a read only memory (ROM), a hard disk drive (HDD), a solid state drive (SSD), or a combination thereof. The communication interface communicates with the substrate processing apparatus 10 via a communication line such as a local area network (LAN).

The first raw material LA and the second raw material LB are examples of the monomer of the film forming material. The first raw material LA is an example of a first monomer, and may be, for example, isocyanate. The second raw material LB is an example of the second monomer, and may be, for example, amine.

The first source gas containing a first raw material gas such as isocyanate and the second source gas containing a second raw material gas such as amine are examples of the film forming gas. For example, the first source gas containing an isocyanate gas and the second source gas containing an amine gas are mixed in the processing space 12 to form an organic film of a polymer having a urea bond on the surface of the substrate W supported by the substrate support 11.

For example, in the substrate processing apparatus 10, linear polyurea can be generated by using diisocyanate as the first monomer and diamine (for example, primary amine) as the second monomer. The combination of diisocyanate and diamine is, for example, the combination of 4,4′-diphenylmethane diisocyanate (MDI) and 1,12-diaminododecane (DAD). The combination of diisocyanate and diamine is, for example, the combination of 1,3-bis(isocyanatomethyl)cyclohexane (H6XDI) and 1,12-diaminododecane (DAD). The combination of diisocyanate and diamine is, for example, the combination of 1,3-bis(isocyanatomethyl)cyclohexane (H6XDI) and 1,3-bis(aminomethyl)cyclohexane (H6XDA). The combination of diisocyanate and diamine is, for example, the combination of 1,3-bis(isocyanatomethyl)cyclohexane (H6XDI) and hexamethylenediamine (HMDA). The combination of diisocyanate and diamine is, for example, the combination of m-xylylenediisocyanate (XDI) and m-xylylenediamine (XDA). The combination of diisocyanate and diamine is, for example, the combination of m-xylylene diisocyanate (XDI) and benzylamine (BA).

For example, in the substrate processing apparatus 10, crosslinkable polyurea can be generated by using diisocyanate as the first monomer and triamine (for example, primary amine) or tetraamine (for example, secondary amine) as the second monomer. Further, in the substrate processing apparatus 10, a trimer having a urea bond can be generated by using monoisocyanate as the first monomer and diamine (for example, primary amine) as the second monomer. Further, in the substrate processing apparatus 10, a dimer having a urea bond can be generated by using monoisocyanate as the first monomer and monoamine (for example, primary amine) as the second monomer.

### (Substrate Processing Method)

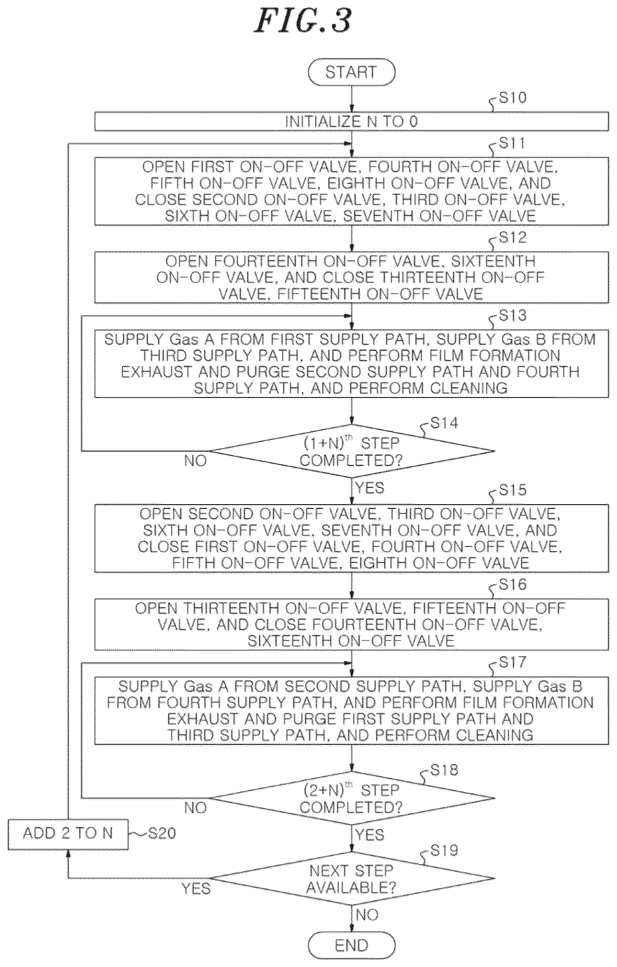

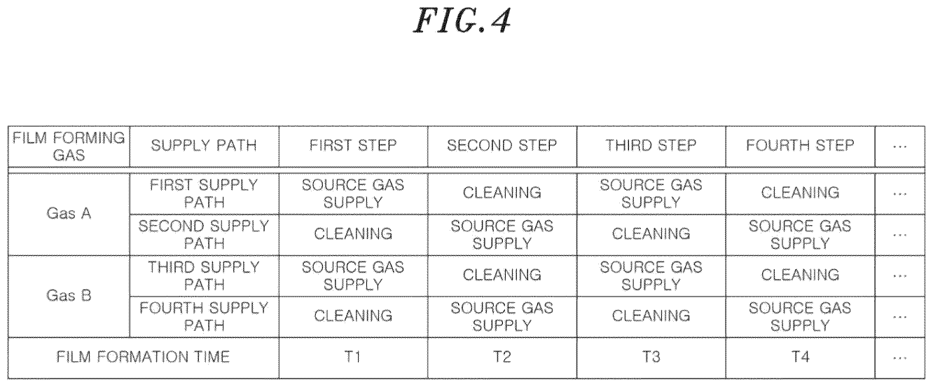

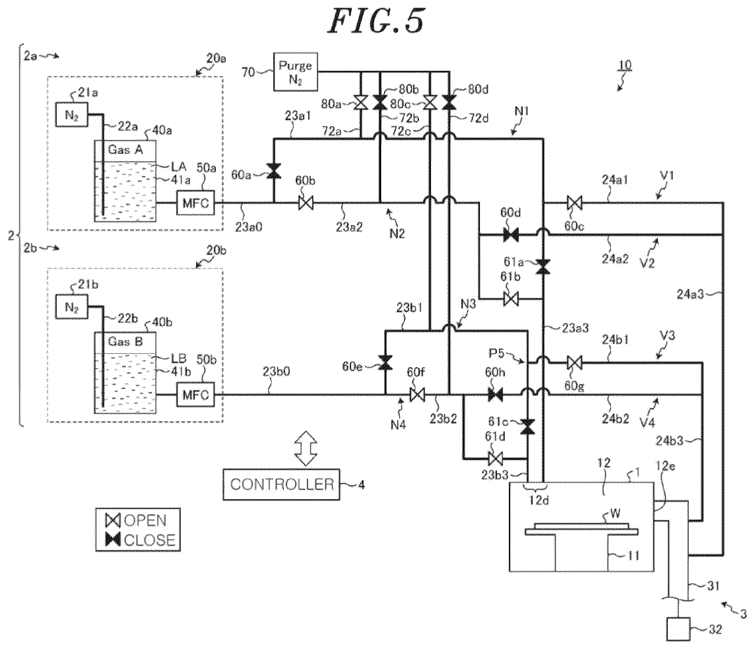

Next, a substrate processing method according to an embodiment of the present disclosure will be described with reference to FIGS. 2 to 5. FIG. 3 is a flowchart showing a substrate processing method according to an embodiment. FIG. 4 is a diagram showing an example of a recipe for simultaneously performing film formation and cleaning. FIGS. 2 and 5 are schematic diagrams of a substrate processing apparatus according to an embodiment.

The substrate processing method may be controlled by the controller 4, and may be performed by the substrate processing apparatus 10. The substrate processing apparatus 10 is an example of a substrate processing apparatus that performs the substrate processing method of the present disclosure, and is not limited thereto.

In the examples shown in FIGS. 2 and 5, the gas used for film formation is the first source gas GasA consisting of the first raw material gas LA and N2 gas, and a second source gas GasB consisting of the second raw material gas LB and N2 gas.

First, in step S10, the controller 4 initializes a variable n related to the number of steps shown in the recipe to 0.

Next, in step S11, the controller 4 controls the first on-off valve 60a and the fourth on-off valve 60d to an open state, and the second on-off valve 60b and the third on-off valve 60c to a closed state. Further, the controller 4 controls the fifth on-off valve 60e and the eighth on-off valve 60h to an open state, and the sixth on-off valve 60f and the seventh on-off valve 60g to a closed state. Further, the controller 4 controls the ninth on-off valve 61a and the eleventh on-off valve 61c to an open state, and the tenth on-off valve 61b and the twelfth on-off valve 61d to a closed state.

Next, in step S12, the controller 4 controls the fourteenth on-off valve 80b and the sixteenth on-off valve 80d to an open state, and the thirteenth on-off valve 80a and the fifteenth on-off valve 80c to a closed state. As a result, as shown in FIG. 2, the opening/closing states of the first on-off valve 60a to the eighth on-off valve 60h, the ninth on-off valve 61a to the twelfth on-off valve 61d, and the thirteenth on-off valve 80a to the sixteenth on-off valve 80d are controlled.

By controlling the opening and closing of each of the on-off valves, in step S13, the controller 4 supplies the first source gas GasA from the first supply path N1 and supplies the second source gas GasB from the third supply path N3. At the same time, the controller 4 exhausts the second supply path N2 through the vent line 24a2 and supplies N2 gas from the second purge gas path 72b to the second supply path N2 to purge the second supply path N2. Further, the controller 4 exhausts the fourth supply path N4 through the vent line 24b2, and supplies N2 gas from the fourth purge gas path 72d to the fourth supply path N4 to purge the fourth supply path N4. However, the controller 4 may purge the second supply path N2 with N2 gas without exhausting the second supply path N2. Further, the controller 4 may purge the fourth supply path N4 with N2 gas without exhausting the fourth supply path N4. As a result, as illustrated in the first step of FIG. 4, the substrate processing apparatus 10 can simultaneously perform the formation of a film using two source gases supplied from the first supply path N1 and the third supply path N3, and the cleaning of the second supply path N2 and the fourth supply path N4. Further, the first to fourth steps are film formation steps. However, each step of the recipe is not limited thereto, and may include steps before and after the film formation step, such as a stabilization step.

Steps S12 and S13 may be performed simultaneously. Steps S12 and S13 may be performed in the reverse order. The supply of the first source gas GasA in steps S11 to S13 is an example of the process (a). The supply of the second source gas GasB in steps S11 to S13 is an example of process (c). The cleaning of the second supply path N2 and the fourth supply path N4 in steps S11 to S13 is an example of the processes (b) and (d).

Next, in step S14, the controller 4 determines whether the (1+n)^{th} step has been completed. Here, n is set to 0. Therefore, the controller 4 determines whether the first step has been completed. The controller 4 determines whether the first step has been completed based on the recipe. For example, in the example of FIG. 4, when film formation time T1 of the first step has elapsed, the controller 4 determines that the first step has been completed. While it is determined that the first step has not been completed, the controller 4 determines “NO” in step S14 and repeats the processes of steps S13 and S14. When it is determined that the first step has been completed, the controller 4 determines “YES” in step S14 and proceeds to step S15.

In step S15, the controller 4 controls the second on-off valve 60b and the third on-off valve 60c to an open state, and controls the first on-off valve 60a and the fourth on-off valve 60d to a closed state. In addition, the controller 4 controls the sixth on-off valve 60f and the seventh on-off valve 60g to an open state, and controls the fifth on-off valve 60e and the eighth on-off valve 60h to a closed state. Further, the controller 4 controls the tenth on-off valve 61b and the twelfth on-off valve 61d to a closed state, and the ninth on-off valve 61a and the eleventh on-off valve 61c to an open state.

Next, in step S16, the controller 4 controls the thirteenth on-off valve 80a and the fifteenth on-off valve 80c to an open state, and controls the fourteenth on-off valve 80b and the sixteenth on-off valve 80d to a closed state. As a result, the opening/closing states of the first on-off valve 60a to the eighth on-off valve 60h, the ninth on-off valve 61a to the twelfth on-off valve 61d, and the thirteenth on-off valve 80a to the sixteenth on-off valve 80d are controlled, as illustrated in FIG. 5.

By controlling the opening and closing of each of the above on-off valves, in step S17, the controller 4 supplies the first source gas GasA from the second supply path N2 and supplies the second source gas GasB from the fourth supply path N4. At the same time, the controller 4 exhausts the first supply path N1 through the vent line 24a1, and supplies N2 gas from the first purge gas path 72a to the first supply path N1 to purge the first supply path N1. Further, the controller 4 exhausts the third supply path N3 through the vent line 24b1, and supplies N2 gas from the third purge gas path 72c to the third supply path N3 to purge the third supply path N3. However, the controller 4 may purge the first supply path N1 with N2 gas without exhausting the first supply path N1. Further, the controller 4 may purge the third supply path N3 with N2 gas without exhausting the third supply path N3. As a result, as illustrated in the second step of FIG. 4, the substrate processing apparatus 10 can simultaneously perform the formation of a film using two source gases supplied from the second supply path N2 and the fourth supply path N4, and the cleaning of the first supply path N1 and the third supply path N3.

The controller 4 may simultaneously perform steps S15 and S16. The order of steps S15 and S16 may be reversed. The supply of the first source gas GasA in steps S15 to S17 is an example of the process (a). The supply of the second source gas GasB in steps S15 to S17 is an example of the process (c). The cleaning of the first supply path N1 and the third supply path N3 in steps S15 to S17 is an example of the processes (b) and (d).

Next, in step S18, the controller 4 determines whether the (2+n)^{th} step has been completed. Here, n is set to 0. Therefore, the controller 4 determines whether the second step has been completed. The controller 4 determines whether the second step has been completed based on the recipe. For example, in the example of FIG. 4, when film formation time T2 of the second step has elapsed, the controller 4 determines that the second step has been completed. While it is determined that the second step has not been completed, the controller 4 determines “NO” in step S18 and repeats the processes of steps S17 and S18. When it is determined that the second step has been completed, the controller 4 determines “YES” in step S18 and proceeds to step S19.

In step S19, the controller 4 determines whether or not there is a next step. The controller 4 determines whether or not there is a next step based on the recipe. For example, in the example of FIG. 4, there is a third step subsequent to the second step. Therefore, the controller 4 determines “YES” in step S19 and proceeds to step S20.

In step S20, the controller 4 adds 2 to the variable n, and returns to step S11. The controller 4 executes the processes of steps S11 to S13. As a result, the opening/closing state of each on-off valve is controlled to the state shown in the example of FIG. 2 again.

In step S14, the controller 4 determines whether the (1+n)^{th} step has been completed. Here, n is set to 2. Therefore, the controller 4 determines whether or not the third step has been completed based on the recipe. When it is determined that the third step has been completed, the controller 4 determines “YES” in step S14 and proceeds to step S15.

The controller 4 executes the processes of steps S15 to S17. As a result, the opening/closing state of each opening/closing value is controlled to the state shown in the example of FIG. 5 again.

In step S18, the controller 4 determines whether or not the (2+n)^{th} step has been completed. Here, n is set to 2. Therefore, the controller 4 determines whether or not the fourth step has been completed based on the recipe. When it is determined that the fourth step has been completed, the controller 4 determines “YES” in step S18 and proceeds to step S19.

In step S19, the controller 4 determines whether or not there is a next step. When it is determined that there is a next step based on the recipe, the controller 4 determines “YES” in step S19 and proceeds to step S20. When it is determined that there is no next step, the controller 4 determines “NO” in step S19 and terminates the process.

### (Effect)

The substrate processing apparatus 10 according to an embodiment of the present disclosure has two systems of gas supply lines and vent lines. The vent line is connected to an exhaust line. With this configuration, in the substrate processing method according to an embodiment of the present disclosure, a source gas is supplied from one of the two systems of gas supply lines into the processing chamber 1 to perform film formation, and the other supply line is exhausted and purged through the vent line connected to the other supply line. Accordingly, the substrate processing apparatus 10 can simultaneously perform the film formation on the substrate and the cleaning of the supply line. Therefore, in the substrate processing apparatus 10, it is no need to add a process of exhausting and purging the supply line after the film formation. As a result, the substrate processing apparatus 10 can reduce particles without reducing throughput. Hence, the substrate processing apparatus 10 can improve the film formation performance without reducing productivity.

Further, the supply lines 23a3 and 23b3 cannot be purged. However, the supply lines 23a3 and 23b3 can be heated by locating a heater therein. Since the supply lines 23a4 and 23b3 are close to the processing chamber 1, it is not likely to decrease a temperature due to heat input from the processing chamber 1, and cold spots are unlikely to occur. In addition, the length of the supply lines 23a3 and 23b3 is only a few percent of the piping length of the entire supply line, and is a few centimeters to several of centimeters, which is short. Therefore, even if the supply lines 23a3 and 23b3 cannot be purged, it does not cause generation of particles.

The substrate processing method according to the present embodiment includes: (a) supplying a first source gas from one of the first supply line or the second supply line into the processing chamber 1; and (b) cleaning the other of the first supply line and the second supply line through a first vent line or a second vent line connected to the other of the first supply line and the second supply line.

For example, in the substrate processing method, in (a), the first source gas may be supplied from one of the first supply line or the second supply line by controlling the first on-off valve 60a and the second on-off valve 60b, and in (b), the other of the first supply line and the second supply line may be cleaned through the first vent line or the second vent line by controlling the third on-off valve 60c and the fourth on-off valve 60d.

Further, in the substrate processing method, a set of the first on-off valve 60a and the fourth on-off valve 60d is set as a first set, and a set of the second on-off valve 60b and the third on-off valve 60c is set as a second set. In (a) and (b), the opening/closing states of the on-off valves of the same set are controlled to be the same for the first and second sets, and the opening/closing states of the on-off valves of different sets are controlled to be different. Accordingly, in the substrate processing method, the first source gas can be supplied from one of the first supply line and the second supply line to form a film while simultaneously cleaning the other of the first supply line and the second supply line.

In addition, in the substrate processing method, in (a) and (b), the opening/closing states of the first and second sets of on-off valves may be alternately switched. Accordingly, the first supply line and the second supply line can be alternately cleaned.

In addition, in the substrate processing method, in (b), the first supply line and the second supply line may be alternately cleaned by alternately flowing a purge gas through the first vent line and the second vent line.

Further, in the substrate processing method, in (b), the first source gas is exhausted alternately through the first vent line and the second vent line, and the purge gas flows alternately through the first vent line and the second vent line, thereby alternately cleaning the first supply line and the second supply line.

Further, the substrate processing method according to the present embodiment may include: (c) supplying a second source gas into the processing chamber from one of the third supply line and the fourth supply line, and (d) cleaning the other of the third supply line and the fourth supply line through the third vent line or the fourth vent line connected to the other of the third supply line and the fourth supply line.

For example, in the substrate processing method, in (c), the second source gas may be supplied from one of the third supply line or the fourth supply line by controlling the fifth on-off valve 60e and the sixth on-off valve 60f, and in (c), the other of the third supply line and the fourth supply line may be cleaned through the third vent line and the fourth vent line by controlling the seventh on-off valve 60g and the eighth on-off valve 60h.

In addition, in the substrate processing method, a set of the fifth on-off valve 60e and the eighth on-off valve 60h is set as a third set, and a set of the sixth on-off valve 60f and the seventh on-off valve 60g is set as a fourth set. In (c) and (d), the opening/closing states of the on-off valves of the same set may be controlled to be the same for the third set and the fourth set, and the opening/closing states of the on-off valves of different sets may be controlled to be different. Thus, in the substrate processing method, the second source gas can be supplied from one of the first supply line and the second supply line to form a film while simultaneously cleaning the other of the first supply line and the second supply line.

Further, in the substrate processing method, in (c) and (d), the opening/closing states of the third and fourth sets of on-off valves may be switched alternately. Accordingly, in the substrate processing method, the third supply line and the fourth supply line can be cleaned alternately.

Further, in the substrate processing method, in (d), by alternately flowing the purge gas through the third vent line and the fourth vent line, the third supply line and the fourth supply line can be cleaned alternately.

In addition, in the substrate processing method, in (d), by alternately exhausting the second source gas through the third vent line and the fourth vent line and alternately flowing the purge gas through the third vent line and the fourth vent line, the third supply line and the fourth supply line can be cleaned alternately.

In the substrate processing method, (a) and (b) may be performed in parallel. For example, in the substrate processing method, (a) and (b) may be performed simultaneously. However, in the substrate processing method, (a) and (b) are not necessarily completely simultaneously, and may be performed partially in parallel. For example, in the substrate processing method, the intermediate processing of (a) and (b) may be performed simultaneously, and the initial processing or the final processing of (a) and (b) may be started or ended at shifted timings.

In the substrate processing method, (c) and (d) may be performed in parallel. For example, in the substrate processing method, (c) and (d) may be performed simultaneously. However, in the substrate processing method, (c) and (d) are necessarily performed completely simultaneously, and may be performed partially in parallel. For example, in the substrate processing method, the intermediate processing of (c) and (d) may be performed simultaneously, and the initial processing or the final processing of (c) and (d) may be started or ended at shifted timings.

According to the description of the embodiment, the substrate processing method according to the embodiment includes the processes (a) and (b). In (a), the first source gas is supplied from one of the first supply line and the second supply line into the processing chamber. In (b), the other of the first supply line and the second supply line is cleaned through the first vent line and the second vent line connected to the other of the first supply line and the second supply line.

Further, the substrate processing apparatus 10 according to the embodiment includes the processing chamber 1, the first supply line, the second supply line, the exhaust line 31, the first vent line, the second vent line, and the controller 4. The first supply line and the second supply line supply the first source gas into the processing chamber. The exhaust line 31 exhausts the gas. The first vent line connects the first supply line and the exhaust line 31. The second vent line connects the second supply line and the exhaust line 31. The controller 4 controls the process including (a) and (b).

Further, the embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

For example, the gas supply part 2 has the first gas supply part 2a and the second gas supply part 2b, but may have at least one of the first gas supply part 2a or the second gas supply part 2b. Further, the gas supply part 2 is not limited thereto, and may have three or more systems of gas supply parts.

Further, the following appendices are disclosed with respect to the above embodiments.

### APPENDIX 1

A substrate processing method performed in a substrate processing apparatus,
wherein the substrate processing apparatus includes:
a processing chamber;
a first supply line configured to supply a first source gas into the processing chamber;
a second supply line configured to supply the first source gas into the processing chamber;
an exhaust line configured to exhaust a gas;
a first vent line that connects the first supply line and the exhaust line; and
a second vent line that connects the second supply line and the exhaust line,
the substrate processing method comprising:
(a) supplying the first source gas into the processing chamber from one of the first supply line and the second supply line; and
(b) cleaning the other of the first supply line and the second supply line through the first vent line or the second vent line connected to the other of the first supply line and the second supply line.

### APPENDIX 2

The substrate processing method of Appendix 1, wherein said (a) and (b) are performed in parallel.

### APPENDIX 3

The substrate processing method of Appendix 1 or 2, wherein the substrate processing apparatus further includes:
a first on-off valve provided in the first supply line;
a second on-off valve provided in the second supply line;
a third on-off valve provided in the first vent line; and
a fourth on-off valve provided in the second vent line,
wherein in said (a), the first source gas is supplied from one of the first supply line and the second supply line by controlling the first on-off valve and the second on-off valve, and
in said (b), the other of the first supply line and the second supply line is cleaned through the first vent line or the second vent line by controlling the third on-off valve and the fourth on-off valve.

### APPENDIX 4

The substrate processing method of Appendix 3, wherein a set of the first on-off valve and the fourth on-off valve is set as a first set, and a set of the second on-off valve and the third on-off valve is set as a second set, and
in said (a) and said (b), for the first set and the second set, the opening/closing states of the on-off valves of the same set are controlled to be the same, and the opening/closing states of the on-off valves of different sets are controlled to be different.

### APPENDIX 5

The substrate processing method of Appendix 4, wherein in said (a) and said (b), the first supply line and the second supply line are alternately cleaned by alternately switching the opening/closing states of the on-off valves of the first set and the second set.

### APPENDIX 6

The substrate processing method of Appendix 5, wherein in said (b), the first supply line and the second supply line are alternately cleaned by alternately flowing the purge gas through the first vent line and the second vent line.

### APPENDIX 7

The substrate processing method of Appendix 5, wherein in said (b), the first supply line and the second supply line are alternately cleaned by alternately exhausting the first source gas through the first vent line and the second vent line and alternately flowing the purge gas through the first vent line and the second vent line.

### APPENDIX 8

The substrate processing method according to any one of Appendices 1 to 7, wherein the substrate processing apparatus further includes:
a third supply line configured to supply a second source gas into the processing chamber;
a fourth supply line configured to supply the second source gas into the processing chamber;
a third vent line that connects the third supply line and the exhaust line; and
a fourth vent line that connects the fourth supply line and the exhaust line, the substrate processing method further comprising:
(c) supplying the second source gas into the processing chamber from one of the third supply line and the fourth supply line; and
(d) cleaning the other of the third supply line and the fourth supply line through the third vent line or the fourth vent line connected to the other of the third supply line and the fourth supply line.

### APPENDIX 9

The substrate processing method of Appendix 8, wherein said (c) and said (d) are performed in parallel.

### APPENDIX 10

The substrate processing method of Appendix 8 or 9, wherein the substrate processing apparatus further includes:
a fifth on-off valve provided in the third supply line;
a sixth on-off valve provided in the fourth supply line;
a seventh on-off valve provided in the third vent line; and
an eighth on-off valve provided in the fourth vent line,
wherein in said (c), the second source gas is supplied from one of the third supply line and the fourth supply line by controlling the fifth on-off valve and the sixth on-off valve; and
in said (d), the other of the third supply line and the fourth supply line is cleaned through the third vent line or the fourth vent line by controlling the seventh on-off valve and the eighth on-off valve.

### APPENDIX 11

The substrate processing method of Appendix 10, wherein a set of the fifth on-off valve and the eighth on-off valve is set as a third set, and a set of the sixth on-off valve and the seventh on-off valve is set as a fourth set, and
in said (c) and said (d), for the third set and the fourth set, the opening/closing states of the on-off valves of the same set are controlled to be the same, and the opening/closing states of the on-off valves of different sets are controlled to be different.

### APPENDIX 12

The substrate processing method of Appendix 11, wherein in said (c) and said (d), the third supply line and the fourth supply line are alternately cleaned by alternately switching the opening/closing states of the on-off valves of the third set and the fourth set.

### APPENDIX 13

The substrate processing method of Appendix 12, wherein in said (d), the third supply line and the fourth supply line are alternately cleaned by alternately flowing the purge gas through the third vent line and the fourth vent line.

### APPENDIX 14

The substrate processing method of Appendix 12, wherein in said (d), the third supply line and the fourth supply line are alternately cleaned by alternately exhausting the second source gas through the third vent line and the fourth vent line, and alternately flowing the purge gas through the third vent line and the fourth vent line.

### APPENDIX 15

A substrate processing apparatus comprising:
a processing chamber;
a first supply line configured to supply a first source gas into the processing chamber;
a second supply line configured to supply the first source gas into the processing chamber;
an exhaust line configured to exhaust a gas;
a first vent line that connects the first supply line and the exhaust line;
a second vent line that connects the second supply line and the exhaust line; and
a controller,
wherein the controller is configured to control:
(a) supplying the first source gas into the processing chamber from one of the first supply line and the second supply line; and
(b) cleaning the other of the first supply line and the second supply line through the first vent line or the second vent line connected to the other of the first supply line and the second supply line.

1. A substrate processing method performed in a substrate processing apparatus,
wherein the substrate processing apparatus includes:
a processing chamber;
a first supply line configured to supply a first source gas into the processing chamber;
a second supply line configured to supply the first source gas into the processing chamber;
an exhaust line configured to exhaust a gas;
a first vent line that connects the first supply line and the exhaust line; and
a second vent line that connects the second supply line and the exhaust line,
the substrate processing method comprising:
(a) supplying the first source gas into the processing chamber from one of the first supply line and the second supply line; and
(b) cleaning the other of the first supply line and the second supply line through the first vent line or the second vent line connected to the other of the first supply line and the second supply line.

2. The substrate processing method of claim 1, wherein said (a) and (b) are performed in parallel.

3. The substrate processing method of claim 1, wherein the substrate processing apparatus further includes:
a first on-off valve provided in the first supply line;
a second on-off valve provided in the second supply line;
a third on-off valve provided in the first vent line; and
a fourth on-off valve provided in the second vent line,
wherein in said (a), the first source gas is supplied from one of the first supply line and the second supply line by controlling the first on-off valve and the second on-off valve, and
in said (b), the other of the first supply line and the second supply line is cleaned through the first vent line or the second vent line by controlling the third on-off valve and the fourth on-off valve.

4. The substrate processing method of claim 3, wherein a set of the first on-off valve and the fourth on-off valve is set as a first set, and a set of the second on-off valve and the third on-off valve is set as a second set, and
in said (a) and said (b), for the first set and the second set, the opening/closing states of the on-off valves of the same set are controlled to be the same, and the opening/closing states of the on-off valves of different sets are controlled to be different.

5. The substrate processing method of claim 4, wherein in said (a) and said (b), the first supply line and the second supply line are alternately cleaned by alternately switching the opening/closing states of the on-off valves of the first set and the second set.

6. The substrate processing method of claim 5, wherein in said (b), the first supply line and the second supply line are alternately cleaned by alternately flowing the purge gas through the first vent line and the second vent line.

7. The substrate processing method of claim 5, wherein in said (b), the first supply line and the second supply line are alternately cleaned by alternately exhausting the first source gas through the first vent line and the second vent line and alternately flowing the purge gas through the first vent line and the second vent line.

8. The substrate processing method according to claim 1, wherein the substrate processing apparatus further includes:
a third supply line configured to supply a second source gas into the processing chamber;
a fourth supply line configured to supply the second source gas into the processing chamber;
a third vent line that connects the third supply line and the exhaust line; and
a fourth vent line that connects the fourth supply line and the exhaust line,
the substrate processing method further comprising:
(c) supplying the second source gas into the processing chamber from one of the third supply line and the fourth supply line; and
(d) cleaning the other of the third supply line and the fourth supply line through the third vent line or the fourth vent line connected to the other of the third supply line and the fourth supply line.

9. The substrate processing method of claim 8, wherein said (c) and said (d) are performed in parallel.

10. The substrate processing method of claim 8, wherein the substrate processing apparatus further includes:
a fifth on-off valve provided in the third supply line;
a sixth on-off valve provided in the fourth supply line;
a seventh on-off valve provided in the third vent line; and
an eighth on-off valve provided in the fourth vent line,
wherein in said (c), the second source gas is supplied from one of the third supply line and the fourth supply line by controlling the fifth on-off valve and the sixth on-off valve; and
in said (d), the other of the third supply line and the fourth supply line is cleaned through the third vent line or the fourth vent line by controlling the seventh on-off valve and the eighth on-off valve.

11. The substrate processing method of claim 10, wherein a set of the fifth on-off valve and the eighth on-off valve is set as a third set, and a set of the sixth on-off valve and the seventh on-off valve is set as a fourth set, and
in said (c) and said (d), for the third set and the fourth set, the opening/closing states of the on-off valves of the same set are controlled to be the same, and the opening/closing states of the on-off valves of different sets are controlled to be different.

12. The substrate processing method of claim 11, wherein in said (c) and said (d), the third supply line and the fourth supply line are alternately cleaned by alternately switching the opening/closing states of the on-off valves of the third set and the fourth set.

13. The substrate processing method of claim 12, wherein in said (d), the third supply line and the fourth supply line are alternately cleaned by alternately flowing the purge gas through the third vent line and the fourth vent line.

14. The substrate processing method of claim 13, wherein in said (d), the third supply line and the fourth supply line are alternately cleaned by alternately exhausting the second source gas through the third vent line and the fourth vent line, and alternately flowing the purge gas through the third vent line and the fourth vent line.

15. A substrate processing apparatus comprising:
a processing chamber;
a first supply line configured to supply a first source gas into the processing chamber;
a second supply line configured to supply the first source gas into the processing chamber;
an exhaust line configured to exhaust a gas;
a first vent line that connects the first supply line and the exhaust line;
a second vent line that connects the second supply line and the exhaust line; and
a controller,
wherein the controller is configured to control:
(a) supplying the first source gas into the processing chamber from one of the first supply line and the second supply line; and
(b) cleaning the other of the first supply line and the second supply line through the first vent line or the second vent line connected to the other of the first supply line and the second supply line.
